(19) United States
(12) Patent Application Publication
(10) Pub. No.: US 2014/0319564 A1
(43) Pub. Date: Oct. 30, 2014

(54) LIGHT EMITTING DIODE PACKAGE AND METHOD FOR MANUCFACTURING SAME

(71) Applicant: ADVANCED OPTOELECTRONIC TECHNOLOGY, INC., Hsinchu Hsien 303 (TW)

(72) Inventors: HOU-TE LIN, Hukou (TW); CHAO-HSIUNG CHANG, Hukou (TW); PIN-CHUAN CHEN, Hukou (TW); LUNG-HSIN CHEN, Hukou (TW)

(73) Assignee: ADVANCED OPTOELECTRONIC TECHNOLOGY, INC., Hsinchu Hsien 303 (TW)

(21) Appl. No.: 14/140,460

(22) Filed: Dec. 24, 2013

(30) Foreign Application Priority Data
Apr. 24, 2013 (CN) 2013101445629

(51) Int. Cl. H01L 33/60

(52) U.S. Cl. CPC H01L 33/60
USPC 257/98; 438/27

(57) ABSTRACT

A light emitting diode package for mounting to a printed circuit board by surface mounting technology includes a substrate, first and second electrodes and a light emitting diode. The first electrode and the second electrode each have a first end and a second end. The second end of the first electrode is adjacent to the first end of the second electrode and a distance therebetween is increased along a top-to-bottom direction of the light emitting diode package. The first end of the first electrode extends out of the substrate and forms a tapered structure. The second end of the second electrode extends out of the substrate and forms a tapered structure. The light emitting diode chip is electrically connected with the first and second electrodes. A method for manufacturing the light emitting diode package is also provided.

### BACKGROUND

1. Technical Field

The disclosure generally relates to a lighting element, and particularly relates to a light emitting diode package with a higher reliability for connection with a printed circuit board by surface mounting technology (SMT) and a method for manufacturing the light emitting diode package.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

A light emitting diode package includes a substrate, electrodes formed on the substrate and a light emitting diode chip formed on the substrate. The light emitting diode chip is electrically connected with the electrodes of the substrate. However, when the light emitting diode package is mounted on a printed circuit board by surface mounting technology, if the electrodes are not sufficiently connected to the printed circuit board, the light emitting diode package may be electrically separated from the printed circuit board due to vibration, which will affect the normal operation of the light emitting diode package.

What is needed, therefore, is a light emitting diode package and a method for manufacturing the light emitting diode package to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross sectional view of a light emitting diode package in accordance with an embodiment of the present disclosure.

FIG. 2 is a top plan view of the light emitting diode package in FIG. 1.

FIG. 3 is cross-sectional view showing a first step of a method for manufacturing the light emitting diode package in FIG. 1.

FIG. 4 is a cross-sectional view showing a second step of the method for manufacturing the light emitting diode package in FIG. 1.

FIG. 5 is a cross-sectional view showing a third step of the method for manufacturing the light emitting diode package in FIG. 1.

FIG. 6 is a cross-sectional view showing a fourth step of the method for manufacturing the light emitting diode package in FIG. 1.

FIG. 7 is a cross-sectional view showing a fifth step of the method for manufacturing the light emitting diode package in FIG. 1.

FIG. 8 is a top plan view of the light emitting diode packages in FIG. 7.

### DETAILED DESCRIPTION

Embodiments of a light emitting diode package and a method for manufacturing the light emitting diode package will now be described in detail below and with reference to the drawings.

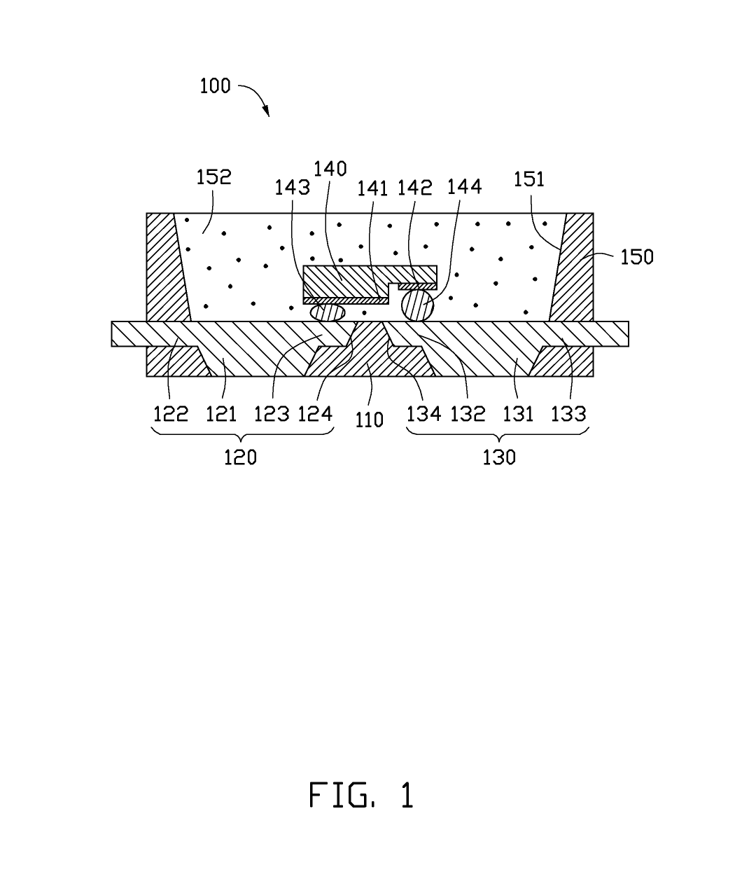

Referring to FIG. 1, a light emitting diode package 100 in accordance with an embodiment is provided. The light emitting diode package 100 includes a substrate 110, a first electrode 120 and a second electrode 130 formed on the substrate 110, and a light emitting diode chip 140 formed on the substrate 110.

The substrate 110 is made of a material selected from one of polyphthalamide (PPA), epoxy and silicone.

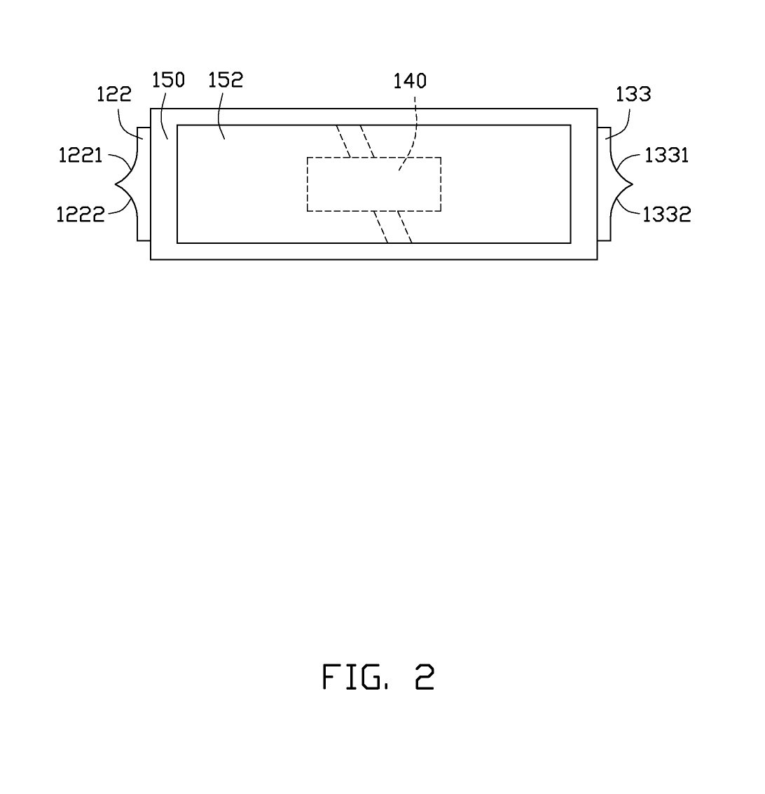

The first electrode 120 includes a main body 121, a first end 122 extending outwardly from the substrate 110, and a second end 123 extending toward the second electrode 130. The second electrode 130 includes a main body 131, a first end 132 extending towards the first electrode 120, and a second end 133 extending outwardly from the substrate 110. The second end 123 of the first electrode 120 is adjacent to the first end 132 of the second electrode 130. Referring also to FIG. 2, the first end 122 of the first electrode 120 includes a first recess 1221 and a second recess 1222. The first recess 1221 and the second recess 1222 together form a tapered structure of the first end 122 which is located at a middle of the first end 122 and tapers off outwardly along a lengthwise direction of the first electrode 120. In this embodiment, the first recess 1221 and the second recess 1222 each are curve-shaped. More specifically the first recess 1221 and the second recess 1222 each are arc-shaped. Similarly, the second end 133 of the second electrode 130 includes a third recess 1331 and a fourth recess 1332. The third recess 1331 and the fourth recess 1332 together form a tapered structure of the second end 133 which is located at a middle of the second end 133 and tapers off outwardly along a lengthwise direction of the second electrode 130. The third recess 1331 and the fourth recess 1332 each are curve-shaped. More specifically the third recess 1331 and the fourth recess 1332 each are arc-shaped. The second end 123 of the first electrode 120 has a first side surface 124. The first end 132 of the second electrode 130 has a second side surface 134. A distance between the first side surface 124 and the second side surface 134 gradually increases from an upper surface to a bottom surface of the substrate 110. When the light emitting diode chip 140 is flip-chip mounted on the substrate 110, the second end 123 of the first electrode 120 and the first end 132 of the second electrode 130 are close enough to electrically connect with electrodes of the light emitting diode chip 140. When the light emitting diode package 100 is are mounted on a printed circuit board (not shown), a distance between bottoms of the first electrode 120 and the second electrode 130 are far enough to avoid short-circuit between the first electrode 120 and the second electrode 130, which may be caused by overflow of solder from one electrode to the other if the distance therebetween is insufficient.

The light emitting diode chip 140 is formed on the substrate 110. The light emitting diode chip 140 includes a positive electrode 141 and a negative electrode 142. The positive electrode 141 is electrically connected with the first electrode 120. The negative electrode 142 is electrically connected with the second electrode 130. In this embodiment, the light emitting diode chip 140 is flip-chip mounted on the substrate 110. The positive electrode 141 of the light emitting diode chip 140 is electrically connected with the first electrode 120 through a first solder ball 143. The negative electrode 142 of the light emitting diode chip 140 is electrically connected with the second electrode 130 through a second solder ball 144.

In the light emitting diode package 100 described above, the first end 122 of the first electrode 120 and the second end 133 of the second electrode 130 extend out of the substrate 110 and each form a tapered structure. When the light emitting diode package 100 is mounted on the printed circuit board, the first end 122 of the first electrode 120 and the second end 133 of the second electrode 130 will contact with more soldering material. Therefore, electrical and mechanical connections between the light emitting diode package 100 and the printed circuit board are improved, whereby the light emitting diode package 100 will not be easily electrically separated from the printed circuit board even if it is subjected to vibration.

Preferably, the light emitting diode package 100 further includes a reflective cup 150. The reflective cup 150 is formed on the first electrode 120 and the second electrode 130. The reflective cup 150 and the substrate 110 can be separately formed or integrally formed as a single piece. The reflective cup 150 is made of a material selected from one of polyphthalamide (PPA), epoxy or silicone. The reflective cup 150 defines a receiving space 151 to receive the light emitting diode chip 140. Reflecting material such as metal can be coated on an inner wall of the reflective cup 150 to increase the light reflecting effectiveness of the reflective cup 150. Preferably, the receiving space 151 can be filled with an encapsulating layer 152 to cover the light emitting diode chip 140. The encapsulating layer 152 can prevent the light emitting diode chip 140 from being affected by moisture or dust in an outer environment. The encapsulating layer 152 can also include phosphor particles or diffusing particles.

A method for manufacturing the light emitting diode package 100 includes following steps.

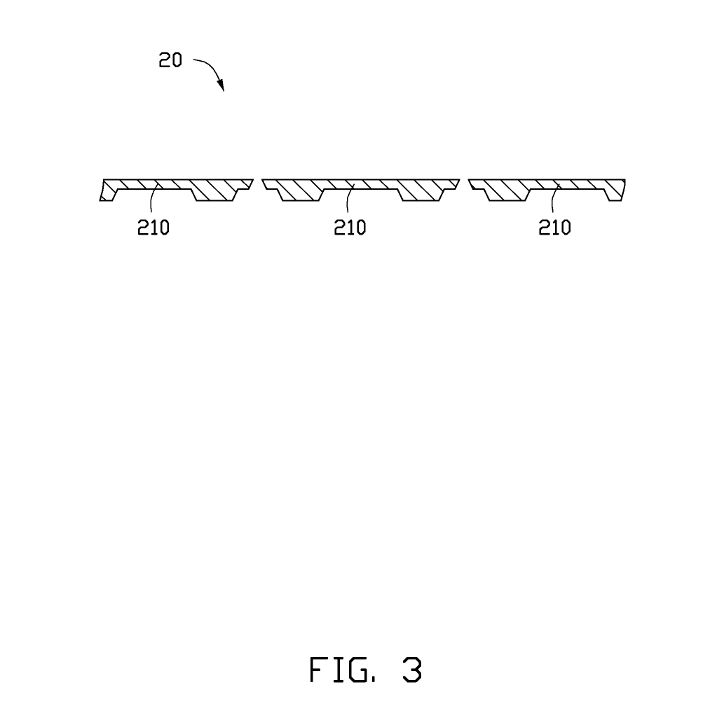

Referring to FIG. 3, an elongate metallic structure 20 is provided. The elongate metallic structure 20 includes a plurality of individual metal frames 210.

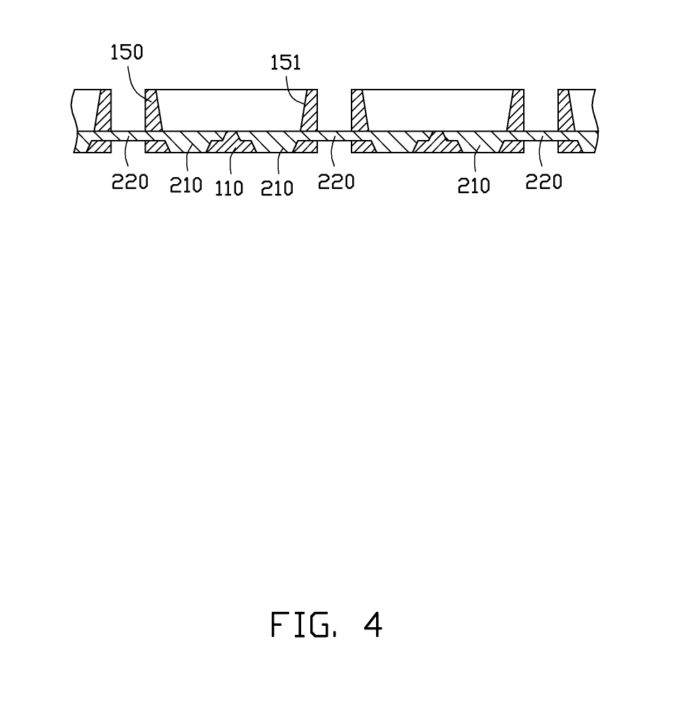

Referring to FIG. 4, a substrate 110 and a reflective cup 150 are formed on neighboring sections of two adjacent metal frames 210. In this embodiment, the substrate 110 and the reflective cup 150 are integrally formed by injection molding as a monolithic piece. The reflective cups 150 each define a receiving space 151 to expose parts of the metal frames 210. After the substrates 110 and the reflective cups 150 are formed, a metal connecting portion 220 is formed between two adjacent reflective cups 150. In this embodiment, the substrates 110 and the reflective cups 150 are made of a material selected from one of polyphthalamide (PPA), epoxy and silicone.

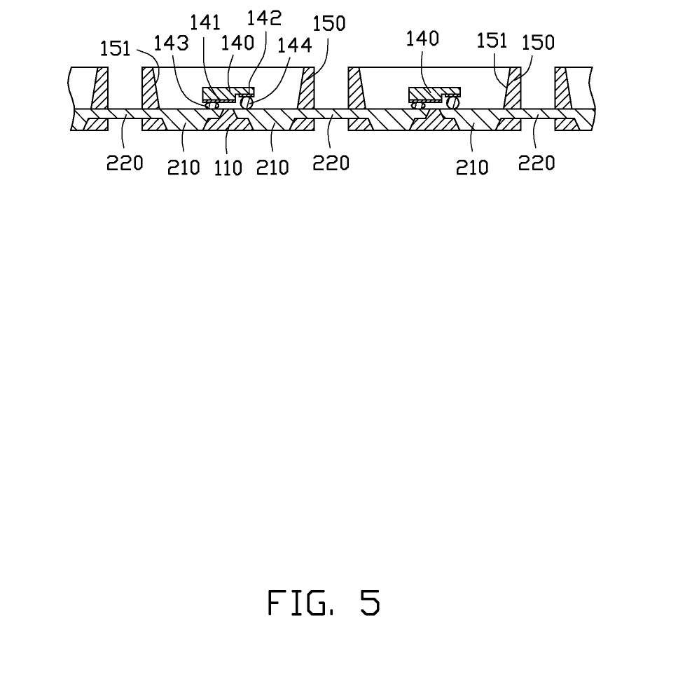

Referring to FIG. 5, a light emitting diode chip 140 is formed inside the receiving space 151 of the reflective cup 150. The light emitting diode chip 140 is flip-chip mounted on the substrate 110. The light emitting diode chip 140 include a positive electrode 141 and a negative electrode 142. The positive electrode 141 is electrically connected with one of the metal frame 210 by a first solder ball 143. The negative electrode 142 is electrically connected with another of the metal frame 210 by a second solder ball 144.

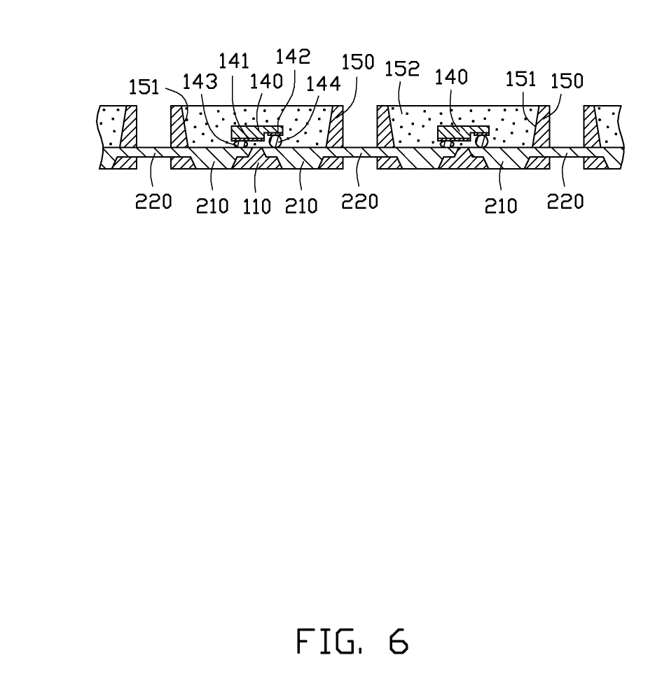

Referring to FIG. 6, an encapsulating layer 152 is filled in the receiving space 151 to cover the light emitting diode chip 140. The encapsulating layer 152 can prevent the light emitting diode chip 140 from being affected by moisture or dust in the outer environment. In addition, the encapsulating layer 152 can also include phosphor particles or diffusing particles.

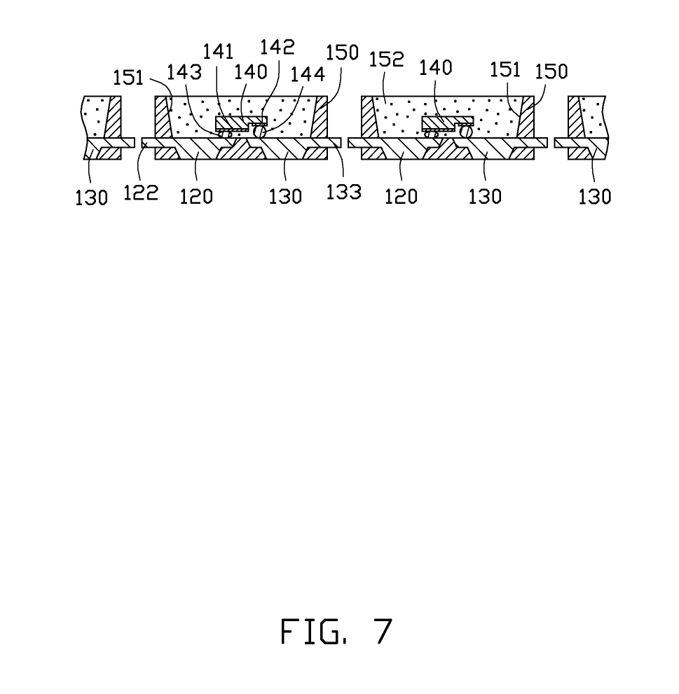

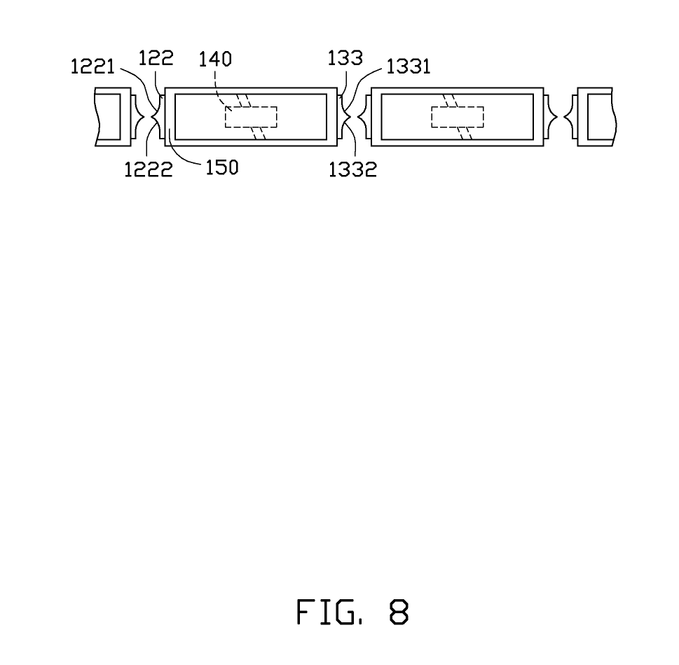

Referring to FIGS. 7-8, the metal connecting portions 220 are etched away to divide the metal frame 210 into a first electrode 120 and a second electrode 130 of two neighboring LED packages 100, respectively. One end of each of the first electrode 120 and the second electrode 130 protrudes out of the substrate 110 and the reflective cup 150 and forms a tapered structure. The first end 122 of the first electrode 120 includes a first recess 1221 and a second recess 1222. The first recess 1221 and the second recess 1222 are adjacent and together form the tapered structure. The second end 133 of the second electrode 130 includes a third recess 1331 and a fourth recess 1332. The third recess 1331 and the fourth recess 1332 are adjacent and together form the tapered structure. In an alternative embodiment, the metal connecting portion 220 can be removed by punching to divide the metal frame 210 into a first electrode 120 and the second electrode 130.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode package configured for connection with a printed circuit board by surface mounting technology, comprising:
a substrate;
a first electrode and a second electrode, formed on the substrate, the first electrode and the second electrode each having a first end and a second end, the second end of the first electrode being adjacent to the first end of the second electrode, the first end of the first electrode extending out of the substrate along a direction away from the second electrode and forming a tapered structure tapering outwardly, the second end of the second electrode extending out of the substrate along a direction away from the first electrode and forming a tapered structure tapering outwardly; and
a light emitting diode chip, formed on the substrate, the light emitting diode chip having a positive electrode and a negative electrode electrically connected with the first electrode and the second electrode respectively.

2. The light emitting diode package of claim 1, wherein the first end of the first electrode comprises a first recess and a second recess, and the first recess and the second recess together form the tapered structure of the first end of the first electrode.

3. The light emitting diode package of claim 2, wherein the first recess and the second recess each are curve-shaped.

4. The light emitting diode package of claim 1, wherein the second end of the second electrode comprises a third recess and a fourth recess, and the third recess and the fourth recess together form the tapered structure of the second end of the second electrode.

5. The light emitting diode package of claim 4, wherein the third recess and the fourth recess each are curve-shaped.

6. The light emitting diode package of claim 1, further comprising a reflective cup located on the substrate, the reflective cup defining a receiving space to receive the light emitting diode chip therein.

7. The light emitting diode package of claim 6, wherein the reflective cup and the substrate are integrally formed as a single piece.

8. The light emitting diode package of claim 6, wherein an encapsulating layer is filled in the receiving space to cover the light emitting diode chip.

9. The light emitting diode package of claim 1, wherein the substrate is made of a material selected from one of polyphthalamide (PPA), epoxy and silicone.

10. The light emitting diode package of claim 1, wherein a space between the first and second electrodes is increased along a direction from a top of the substrate adjacent to the light emitting diode chip to a bottom of the substrate distant from the light emitting diode chip.

11. A method for manufacturing a light emitting diode package configured for connection to a printed circuit board by surface mounting technology, comprising following steps:
providing an elongate metallic structure, comprising a plurality of individual metal frames;
forming a substrate and a reflective cup to connect two neighboring portions of two adjacent ones of the metal frames, a metal connecting portion being formed between two adjacent reflective cups, each reflective cup defining a receiving space to expose parts of the two adjacent ones of the metal frames;
arranging a light emitting diode chip inside the receiving space, the light emitting diode chip having a positive electrode and a negative electrode to electrically connect with the exposed parts of the two adjacent ones of the metal frames respectively; and
etching the metal connecting portion away to divide the metal frame into a first electrode and a second electrode of two neighboring light emitting diode packages, ends of the first electrode and the second electrode each protruding out of a corresponding substrate and a corresponding reflective cup and forming a tapered structure.

12. The method of claim 11, wherein the tapered structure comprises two adjacent recesses.

13. The method of claim 12, wherein the recesses each are curve-shaped.

14. The method of claim 11, wherein an encapsulating layer is filled in the receiving space to cover the light emitting diode chip.

15. The method of claim 11, wherein the substrate and the reflective cup are made of a material selected from one of polyphthalamide (PPA), epoxy and silicone.

16. The method of claim 11, wherein the first and second electrodes of a light emitting diode package is spaced from each other a distance which is increased along a direction from a top of the substrate adjacent to the light emitting diode chip to a bottom of the substrate distant from the light emitting diode chip.
